(19) United States
(12) Patent Application Publication
(10) Pub. No.: US 2017/0280581 A1
(43) Pub. Date: Sep. 28, 2017

(54) Rack Server Housing

(71) Applicant: FUJITSU LIMITED, Kawasaki-shi (JP)

(72) Inventor: Ronny Hesse, Bad Lippspringe (DE)

(73) Assignee: FUJITSU LIMITED, Kawasaki-shi (JP)

(21) Appl. No.: 15/465,689

(22) Filed: Mar. 22, 2017

(30) Foreign Application Priority Data
Mar. 22, 2016 (DE) 102016105320.1

(51) Int. Cl. H05K 7/14; H05K 7/18; H05K 7/20

(52) U.S. Cl. CPC H05K 7/1488; H05K 7/20172; H05K 7/18

(57) ABSTRACT

A rack server housing including a housing bottom with opposite side panels and first through third cover elements. The first and second cover element each have one similar fastening recess and are fixed to the side panels. The two fastening recesses are arranged point-symmetrically to one another. The third cover element is insertable into the first and second cover elements in such a way that in a first state in each case one engagement element of the cover element is arranged in a respective fastening recess and the third cover element can be slid from the first state to a second state both along a first direction and a second direction opposite said first direction, so that the third cover element takes at least a form-fit connection to the first and the second cover element via the engagement elements.

The invention relates to a rack server housing having a housing bottom and two opposite side panels.

Rack servers, which typically have a rack server housing, are known from the prior art. A large number of components of the rack server, for example hard disks, fans, boards and so on, are arranged inside the rack server housing. These components are surrounded by several panels of the rack server housing for protection. In the event of maintenance of the rack server, it is necessary to open the latter, which is typically done via a cover side. So that the entire cover side does not have to be opened in the event of maintenance, the cover panel is divided into several partial elements. In this way, it is not necessary for all of the partial elements to be removed in order to gain access to certain components such as fans.

An object of the present invention is to specify a rack server housing that contributes to cost-effective production.

A rack server housing is disclosed which has a housing bottom and, arranged thereon, opposite side panels. The rack server housing has a first cover element and a second cover element which, in an peripheral region, each have at least one identically shaped fastening recess, wherein the first cover element and the second cover element are fixed to the side panels in such a way that the two peripheral regions point to one another at a distance and the two fastening recesses are arranged with point symmetry in relation to each other. Moreover, the rack server housing has a third cover element, which can be inserted into the first cover element and the second cover element in such a way that, in a first state, an engagement element of each cover element is arranged in a corresponding fastening recess and the third cover element can be slid from the first state to a second state both along a first direction and also along a second direction opposite to the first direction, such that the third cover element forms, via the engagement elements, an at least form-fit connection to the first cover element and second cover element.

The cover elements form a common covering or a common cover element when the third cover element is connected with form-fit engagement to the first two cover elements. For example, the cover elements end substantially flush and form a common cover surface.

The fastening recesses and the engagement elements interacting correspondingly with these are configured in such a way that both a sliding of an inserted third cover plate in the first direction and also in the second direction leads to a form-fit engagement on the corresponding first and second cover element. In other words, the fastening recesses and the engagement elements are configured in such a way that a sliding of the third cover element, located in the first state, away from the first cover element or towards the latter (reverse of the second cover element) in each case leads to a mechanical form fit. The engagement elements thus interact mechanically in the area of the fastening recesses with the first and second cover elements.

Optionally, the engagement elements and fastening recesses are configured in such a way that, in addition to the form-fit engagement, a force-fit engagement is achieved in the second state of the third cover element. This contributes to a secure mechanical fastening of the third cover element on the rack server housing.

It is thereby possible for the first and second cover elements to be configured identically at least in the peripheral region with the fastening recesses. In this way, for example, production costs can be reduced, since only one punching, embossing or forming tool is needed for the peripheral region with the fastening recess. Furthermore, it is also possible to arrange the first and second cover elements the other way round if so desired, in which case, however, a form-fit connection to the first and second cover elements can be produced by means of the third cover element. This contributes to structural flexibility. The first cover element and second cover element are mutually offset by 180°, for example, with respect to a rotation axis that runs perpendicularly to the housing bottom.

According to one embodiment, the peripheral regions of the first cover element and second cover element have a support face for the third cover element, on which the third cover element rests in the first state and onto which the third cover element is slid to the second state, wherein the sliding takes place in a predefined direction. The sliding of the third cover element preferably takes place parallel to the common cover surface. In other words, the sliding takes place parallel to a main plane of extent of the third cover element, parallel to an insertion direction of the rack server housing into a server rack. The direction is predefined, for example, by geometric or structural boundary conditions. On account of the predefined direction, the sliding is possible only in one direction.

The predefined direction preferably corresponds to a flow direction of an air stream which is generated by fans that are arranged in the rack server housing. This has the advantage that the sliding on the support face leads to a greater overlap of the third cover element with the peripheral region of the cover element that is arranged downstream in the flow direction. In other words, the overlap with the first or second cover element enlarges depending on whether the sliding is in the direction of the first or second cover element. This enlarged overlap has the advantage that an increased and/or mechanically improved seal against the air pressure generated by the fans can be achieved. Inadvertent release of the third cover plate can thereby be avoided or at least prevented.

According to a further embodiment, the third cover element has at least one coupling element which, in the first state, engages into a slotted linke-like recess which is configured such that it defines the predefined direction for the sliding to the second state. The slotted linke-like recess corresponds to a geometric stipulation for enforcing the predefined direction. For example, the slotted link-like recess is formed in one or both side panels of the rack server housing. For example, a profile of the recess is L-shaped, such that the third cover element can be inserted into the recess in an insertion direction and can then be slid in the first or second direction. The insertion direction extends, for example, perpendicular to the housing bottom. The coupling element is, for example, a pin, peg, bolt, a pin-shaped element or the like.

According to a further embodiment, the first and second cover elements are of identical construction. It is thus possible not only for the two peripheral regions to have an identical design, but for the entire cover element. In this way, two different cover elements are not needed, and instead there only has to be one cover element in duplicate. In this way, only one production process is needed for the one cover element. This contributes to cost-effective production since the corresponding tools and machines have to be made available only for the one cover element, and the cover element can be produced in a higher batch number.

According to a further embodiment, the fastening recesses are each T-shaped, and the engagement elements are each configured as an L-shaped lug.

According to a further embodiment, the fastening recesses are each I-shaped, and the engagement elements are each U-shaped. In other words, the fastening recesses are “bone-like” and the engagement elements are “bridge-like”.

The aforementioned embodiments of the fastening recesses and engagement elements make it possible to produce a form-fit engagement with the third cover element that can be achieved both in the first direction and also in the second direction.

According to a further embodiment, each engagement element has a contact face which, in the second state, is in contact with the corresponding first or second housing cover, wherein the contact face has a predetermined inclination with respect to a main plane of extent of the third cover element. On account of the inclination, a clamping effect is achieved when the third cover element is slid to the second state. In this way, the third cover element is secured with form-fit and force-fit engagement on the first and second cover element.

According to a further embodiment, the third cover element can be arranged in a predefined orientation between the first and second cover element. In this way, the third cover element can be arranged between the first and second cover element only in one defined orientation. In other words, the orientation of the third cover element is “coded”. This can be achieved, for example, on the basis of geometric boundary conditions such as the abovementioned coupling elements and by the slotted link-like recess. This “coding” contributes to simple and rapid assembly.

According to a further embodiment, the third housing cover latches or locks in the second state and/or is secured in the second state by means of a fastening element. For example, a quick-action closure is provided, such that the third cover element is secured mechanically in the second state. Possible fastening means are screws or rivets, for example.

According to a further embodiment, the third cover element is a fan cover. The fan cover can thus be rapidly removed or dismantled during operation in order to be able to gain access to one or more fans that are arranged in the rack server housing. It is not necessary in this case to remove other covers, such as the first or second cover element.

Further advantageous embodiments are disclosed in the following detailed description of an illustrative embodiment.

The illustrative embodiment is described below with reference to the attached figures. Elements that are similar or that have a similar action are provided with the same reference signs throughout the figures.

In the figures:

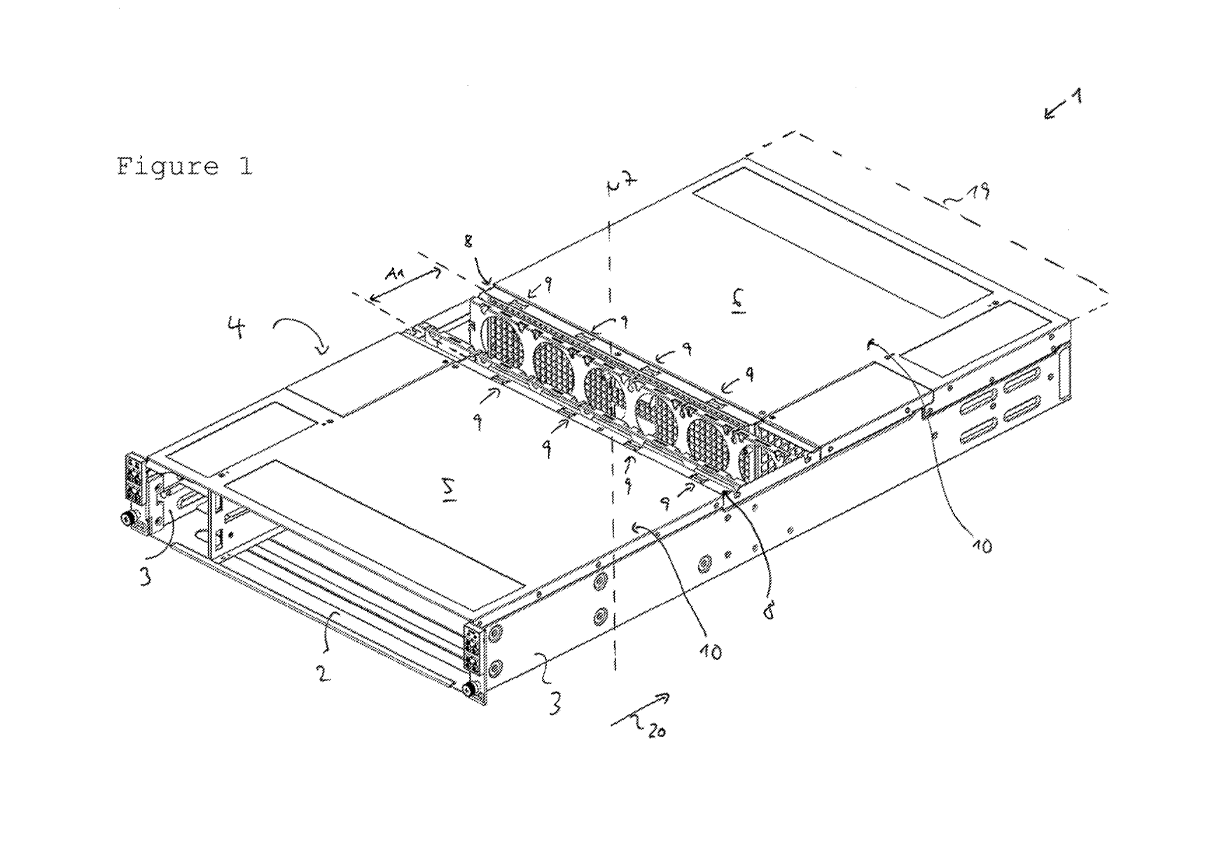

FIG. 1 shows a perspective view of a rack server housing,

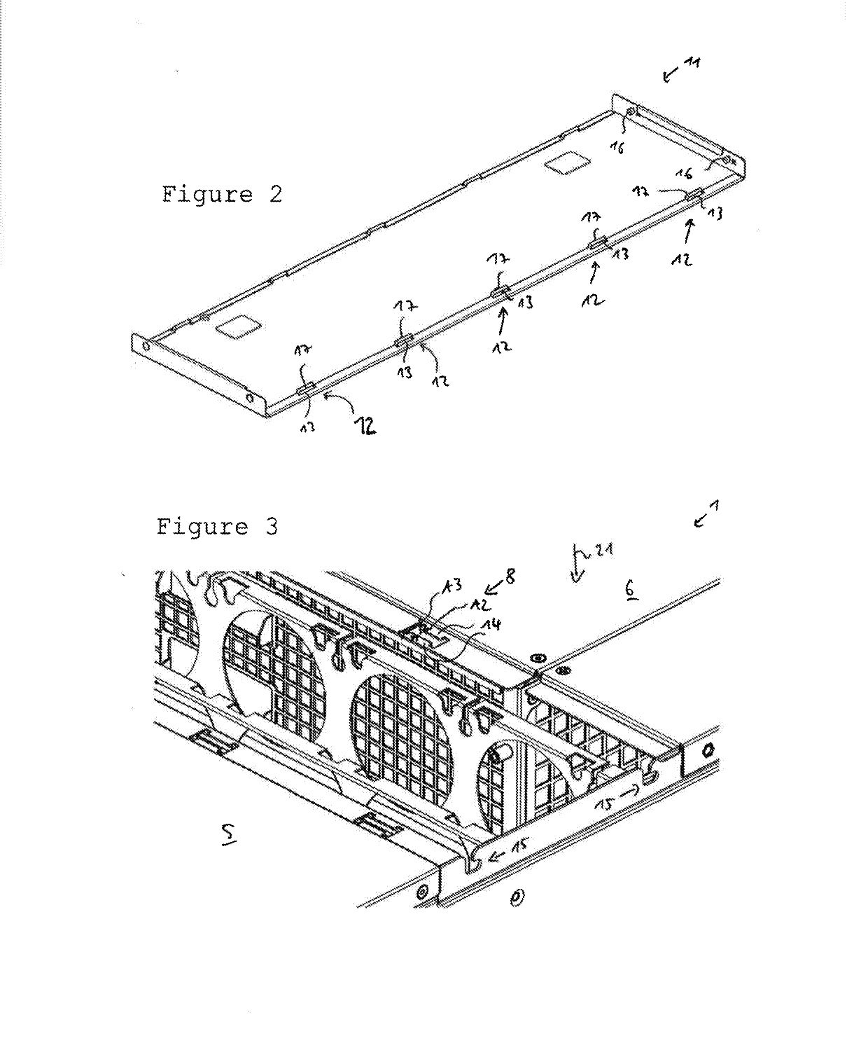

FIG. 2 shows a perspective bottom view of a cover element for the rack server housing according to FIG. 1,

FIG. 3 shows an enlarged perspective partial view of the rack server housing according to FIG. 1,

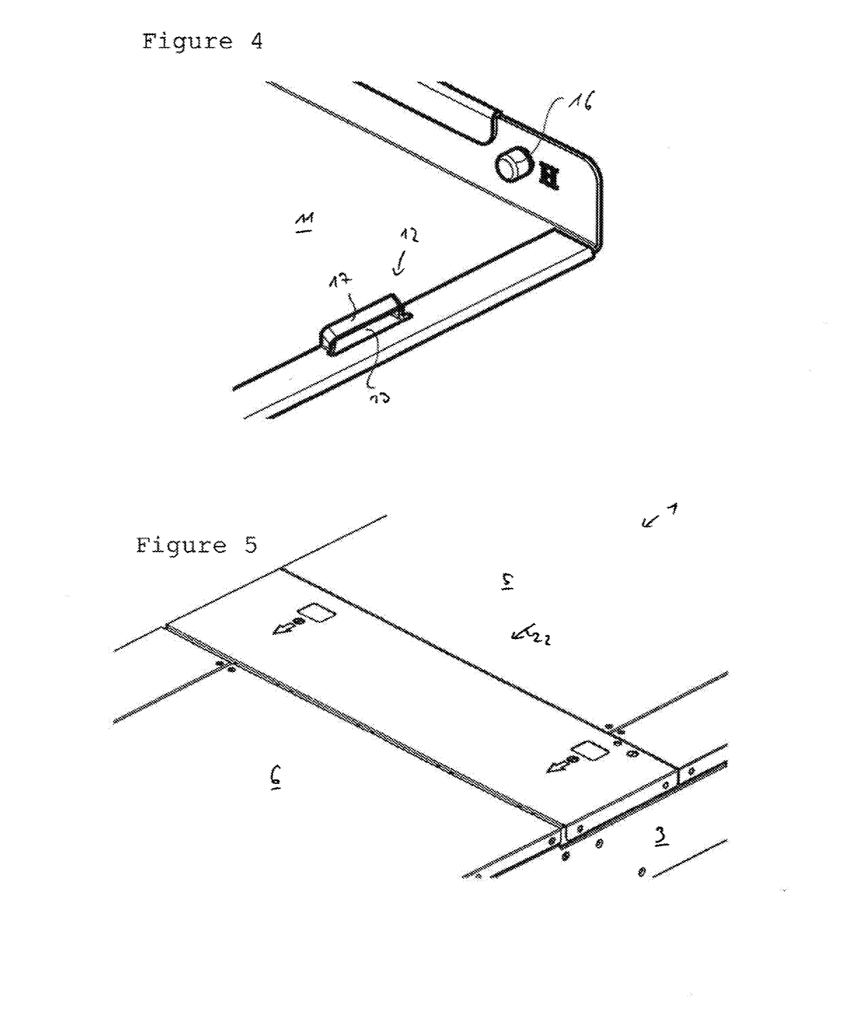

FIG. 4 shows an enlarged perspective partial view of the cover element,

FIG. 5 shows a perspective detail of the rack server housing with inserted cover element according to FIG. 3,

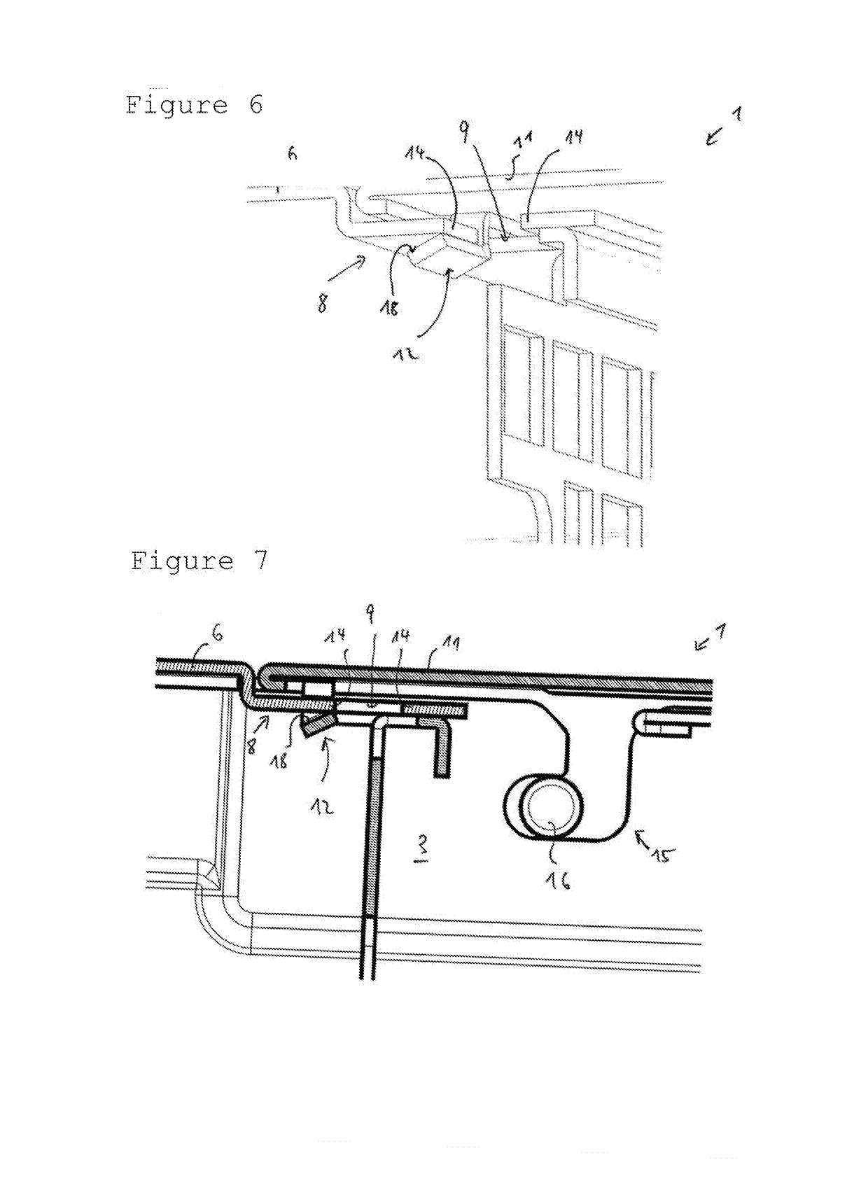

FIG. 6 shows a perspective partial sectional view of the rack server housing with inserted cover element, and

FIG. 7 shows a detail of a cross-sectional view of the rack server housing with inserted cover element.

FIG. 1 shows a perspective view of a rack server housing 1 for a server rack. Several components such as processors, hard-disk drives or the like, not described in any more detail, are arranged or can be arranged in the rack server housing 1. The rack server housing 1 is typically pushed into a rack along with its components arranged in the interior.

The rack server housing 1 has a housing bottom 2 and, arranged thereon, opposite side panels 3. On a top 4 of the rack server, lying opposite the housing bottom 2, several cover elements are provided which together form a common cover or a common covering. The rack server housing 1 has a first cover element 5 and a second cover element 6. The two cover elements 5, 6 are of identical configuration and are fixed to the side panels 3. For example, the first cover element 5 and second cover element 6 are riveted to the side panels. The housing bottom 2, the side panels 3 and the cover elements 5, 6 are shaped from metal sheets.

The first cover element 5 and second cover element 6 are in this case rotated through 180° about a point symmetry axis 7 and are offset in a common plane 19. The plane 19 corresponds to a main plane of extent of the two cover elements 5, 6. In the assembled state according to FIG. 1, the cover elements 5, 6 define a common cover surface 10, which extends parallel to the plane 19. Each of the two cover elements 5 and 6 has an peripheral region 8, which extends substantially along an edge. The peripheral region 8 is configured as assembly area with a stepped lug and has several fastening recesses 9. The stepped lugs are offset in parallel slightly inwards in relation to the common cover surface 10 in the direction of the housing bottom 2. The two peripheral regions 8 face each other in the assembled or fixed state. The two cover elements 5, 6 point to one another at a first distance A1. The peripheral regions 8 form a support face for a further, third cover element, which is described later.

The area of the interior of the rack server housing 1, lying between the two cover elements 5 and 6 of the rack server housing 1, is provided for receiving several fans in order to form a fan bank. These can be inserted into the rack server housing 1 or dismantled without the need to remove the cover elements 5, 6 as shown in FIG. 1.

FIG. 2 shows a perspective view of a third cover element 11 from an underside, which third cover element 11 is inserted between the first and second cover elements 5, 6. For this purpose, the third cover element 11 has, on both sides, several engagement elements 12 designed as U-shaped lugs. The U-shaped lugs each delimit an opening 13 (see also FIG. 4).

FIG. 3 shows an enlarged partial sectional view of the rack server housing 1 shown in FIG. 1, in which the three fastening recesses 9 are shown enlarged. The fastening recesses 9 are introduced in an I shape (also designated as a double T shape) into the peripheral regions 8 of the first cover element 5 and second cover element 6. They have a central area with a second distance A2 between two opposite edges and, laterally adjacent to the central area, in each case an area with a third distance A3, greater than the second distance A2, between two opposite edges. The edges extend parallel to the cover surface 10 and perpendicular to an insertion direction 20 of the rack server housing 1 (see arrow in FIG. 1). The described shape results in two inwardly facing webs 14 of the cover elements 5, 6 for each fastening recess 9.

It will also be seen from FIG. 3 that two slotted link-like recesses 15 are incorporated laterally into each side panel 3. The slotted link-like recesses 15 have an upwardly open, L-shaped profile. Corresponding to this, as is shown in FIG. 2, the third cover element 11 has two projections 16, which represent coupling elements, on opposite side lugs. The projections 16 are designed like pins, for example as bolts, and have a cylindrical form (see FIG. 4). The slotted link-like recesses 15 offer at least partially a positive guide, in particular a bilateral positive guide, for the projections 16.

The third cover plate 11, which can also be designated as a fan cover plate, is mounted in such a way that it is inserted in a first assembly direction 21 into the first cover element 5 and second cover element 6 (see FIG. 2). The engagement elements 12 pass through the fastening recesses 9, and the projections 16 engage in the slotted link-like recesses 15. On account of the projections 16 and the slotted link-like recess 15, the cover element 11 can only be inserted in a certain orientation between the two first and second cover elements 5 and 6.

This first assembly state is shown in FIG. 5. It should be noted that the rack server housing 1 in FIG. 5 has been turned through 180° in relation to FIG. 1. In this state, the first, second and third cover elements 5, 6 and 11 end flush, in such a way that they form the common cover surface 10.

Thereafter, the third cover element 11 is pushed in a predefined second assembly direction 22, which is enforced by the geometric conditions of the slot recesses 15 and corresponds to the insertion direction 20, towards the second cover element 6. The engagement elements 12 each engage around one of the two webs 14 of the fastening recesses 9 of the first and second cover element 5, 6.

On account of the predefined direction, the third cover element 11 moves away from the first cover element 5 and towards the second cover element 6. On account of the fact that the fastening recesses 9 are point-symmetrical and of identical configuration, a form-fit connection to the first cover element 5 and second cover element 6 is achieved via each engagement element 12. In other words, the fastening recesses 9 and the corresponding engagement elements 12 are configured such that, irrespective of the direction of sliding of the third cover element 11, a form-fit connection is obtained both with the first cover element 5 and also with the second cover element 6. It would thus be conceivable, for example, that the slotted link-like recesses 15, in particular a portion extending parallel to the insertion direction 20, point in the other direction and the cover element 11 could be slid in the direction of the first cover element 5, wherein the predefined direction is opposite to the insertion direction 20.

This second assembly state is shown in FIGS. 6 and 7 in a perspective view and in a cross-sectional view. It will be seen that the engagement elements 12 engage behind the webs 14 and, therefore, the first cover element 5 and second cover element 6. The form-fit connection is obtained in this way with the first cover element 5 and second cover element 6.

It will additionally be seen in FIGS. 6 and 7 that a central web portion 17 of each engagement element 12 has an inward contact face 18, which is tilted. On account of the inclined contact face 18, a clamping effect is obtained, such that the third cover element 11 is secured on the first cover element 5 and second cover element 6 not only with form-fit engagement but also with force-fit engagement.

The direction of sliding of the third cover element 11 from the first state to the second state is chosen such that this direction corresponds to an air flow direction that would be generated by fans arranged in the rack server housing 1. This has the advantage that the peripheral region 8 of the second cover element 6, in the direction of which the third cover element 11 is slid, experiences a greater overlap than the peripheral region 8 of the first cover element 5 from which the third cover element 11 moves away. On account of this overlap, openings are avoided or at least reduced in the area of the overlap with the second cover element 6. This contributes to sealing on the side of the fans that is exposed to an increased air pressure on account of the fans.

It will also be seen in FIG. 5 that the cover elements 5, 6 and 11 are designed such that, after the displacement of the third cover element 11 in the second assembly direction 22, no openings such as assembly holes or parts of the fastening recesses 9 lie at least partially exposed. In this way, undesired effects such as flow effects for the fans or the like are avoided. In other words, measures are taken in the adjoining parts of the three cover elements 5, 6 and 11 that can be reused by the symmetry.

Optionally the third cover element 11 can be secured via additional securing means such as rivets, screws, latches or the like and/or by quick-action closure mechanisms.

The described illustrative embodiment permits the advantages and functions mentioned at the outset, in particular a cost-effective production of the rack server housing 1. On account of the fact that the first cover element 5 and second cover element 6 are of identical construction, or of identical construction at least in the peripheral regions 8, the production process is simplified and can be more cost-effective compared to different cover elements 5, 6. The third cover element 11 is easy to handle in this symmetrical configuration and the available volume and possible movement directions for fixing the third cover element 11 optimally exploited. It will be noted that the embodiment of the correspondingly interacting engagement elements 12 and fastening recesses 9 can also be differently configured in order to effect a form-fit and/or force-fit engagement in two sliding directions of the third cover element 11. For example, the engagement elements 12 are L-shaped and the fastening recesses 9 are T-shaped, wherein the working principle remains substantially unchanged. Another alternative is to design the engagement elements 12 as T-bolts which engage in fastening recesses 9 designed as oblong holes, wherein the oblong holes extend parallel to the insertion direction 20. For example, a clamping action can be achieved in the second state of the third cover element 11 by the fact that the oblong holes taper in the direction of their opposite ends and the bolts are thus clamped.

### LIST OF REFERENCE SIGNS

1 rack server housing
2 housing bottom
3 side panel
4 top
5 first cover element
6 second cover element
7 point symmetry axis
8 peripheral region
9 fastening recess
10 cover surface
11 third cover element
12 engagement element
13 opening
14 web
15 slotted link-like recess
16 projection
17 central web portion
18 contact face
19 plane
20 insertion direction
21 first assembly direction
22 second assembly direction
A1 first distance
A2 second distance
A3 third distance

1. Rack server housing, comprising
a housing bottom with opposite side panels arranged thereon,
a first and a second cover element, which each have one similar fastening recess in a peripheral region, wherein the first and second cover element are fixed to the side panels in such a way that the two peripheral regions point to one another at a distance and the two fastening recesses are arranged point-symmetrically to one another;
a third cover element which is insertable into the first and second cover element in such a way that in a first state in each case one engagement element of the cover element is arranged in a respective fastening recess and the third cover element can be slid from the first state to a second state both along a first direction and along a second direction opposite to said first direction, so that the third cover element takes at least a form-fit connection to the first and the second cover element via the engagement elements.

2. Rack server housing according to claim 1, wherein the peripheral regions of the first and second cover elements have a support face for the third cover element, on which the third cover element rests in the first state and onto which the third cover element is slid to the second state, wherein said sliding is effected in a predetermined direction.

3. Rack server housing according to claim 2, wherein the third cover element has at least one coupling element which, in the first state, engages into a slotted link-like recess that is designed such that it defines the predetermined direction.

4. Rack server housing according to claim 1, wherein the first and the second cover element are identically constructed.

5. Rack server housing according to claim 1, wherein the fastening recesses each have a T-shaped design and the engagement elements are each designed as an L-shaped lug.

6. Rack server housing according to claim 1, wherein the fastening recesses each have an I-shaped design and the engagement elements each have a U-shaped design.

7. Rack server housing according to claim 1, wherein each engagement element has a respective contact face which contacts the respective first and second cover element in the second state, wherein the contact face has a predetermined inclination relative to a main extension plane of the third cover element.

8. Rack server housing according to claim 1, wherein the third cover element can be arranged in a predetermined orientation between the first and the second cover element.

9. Rack server housing according to claim 1, wherein in the second state the third cover element is latched, locked and/or secured by means of a fastening element.

10. Rack server housing according to claim 1, wherein the third cover element is a fan cover.
